(19) United States
(12) Patent Application Publication
(10) Pub. No.: US 2014/0296437 A1
(43) Pub. Date: Oct. 2, 2014

(54) Vinyl Polymer Powder, Curable Resin Composition and Cured Product

(71) Applicant: Mitsubishi Rayon Co., Ltd., Tokyo (JP)

(72) Inventors: Youko Hatae, Hiroshima (JP); Toshihiro Kasai, Aichi (JP)

(73) Assignee: MITSUBISHI RAYON CO., LTD., Tokyo (JP)

(21) Appl. No.: 14/353,906

(22) PCT Filed: Oct. 29, 2012
(86) PCT No.: PCT/JP2012/077835

§ 371 Date: Apr. 24, 2014

(30) Foreign Application Priority Data
Oct. 27, 2011 (JP) 2011-235751

(51) Int. Cl. C08F 265/06; H01L 33/56; C08L 63/00

(52) U.S. Cl. CPC C08F 265/06; C08L 63/00; H01L 33/56
USPC 525/65; 525/289; 428/402

(57) ABSTRACT

A vinyl polymer powder, a curable resin composition containing the vinyl polymer powder and a curable resin, and a cured product obtained by curing the curable resin composition are provided. The vinyl polymer powder contains a vinyl polymer of which the glass transition temperature is 120° C. or higher and the mass average molecular weight is 100,000 or more, has excellent dispersibility in the curable resin composition, and rapidly turns the curable resin composition into a gel state by heating at a predetermined temperature in a short time. Further, the vinyl polymer powder decreases the linear expansion coefficient of the obtained cured product, and improves the crack resistance.

### BACKGROUND OF THE INVENTION

1. Technical Field

The invention relates to a vinyl polymer powder, a curable resin composition containing the vinyl polymer powder, and a cured product from the curable resin composition.

2. Description of Related Art

With advances in IT-related techniques such as mobile devices, digital appliances, communication devices, electronic devices for vehicle, and so on, the resin materials used in the electronics field are considered important. For example, there is a rapidly increasing demand for thermosetting resins or active energy line-curable resins, such as epoxy resins, polyimide resins, curable acrylic resins, and curable oxetanic resins, that are excellent in heat resistance or insulating properties, etc.

In particular, epoxy resin is a material excellent in the mechanical properties, electrical insulation and adhesion, and has characteristics such as little shrinkage on curing. Hence, it is extensively used in semiconductor sealing materials or various insulating materials and adhesives, etc. Among epoxy resins, those in a liquid state at normal temperature are usable for casting or coating at normal temperature and are therefore used as various paste-like or film-like materials.

In recent years, along with the high integration of circuits, demands for precise processing, such as precise pouring or coating using a dispenser, precise pattern coating by screen printing, and coating on a film with high thickness precision, have increased.

However, epoxy resin compositions have high temperature dependency of viscosity so that their viscosity is remarkably reduced due to a rise in temperature for the curing, and high-precision coating and pattern formation are difficult. Especially in the field of electronic materials, since the demand for high precision processing has increased year by year, there is an extremely strong call for the epoxy resin composition to be used to have viscosity that is not reduced even if the temperature rises or have a shape that may be stabilized as soon as possible.

A method of imparting the above properties to an epoxy resin composition is proposed as follows. A specific vinyl polymer, as a gelation property imparting agent (hereinafter referred to as “pre-gelatinizing agent”), is mixed into the epoxy resin composition, so that the epoxy resin composition is rapidly turned into a gel state by heating. For example, in Patent Document 1, a method that uses a specific vinyl polymer as a pre-gelatinizing agent is proposed.

In addition, in recent years, the demand for long-term reliability of electronic materials has increased, and it is required to improve crack resistance of curable resin compositions and to suppress crack destruction caused by temperature cycles. A main reason for occurrence of crack lies in difference in linear expansion coefficient between a curable resin composition and an inorganic material, and elastic modulus of a cured product. Thus, it is considered to suppress the crack by decreasing the linear expansion coefficient and elastic modulus of the cured product.

In response to this demand, in the prior art, a method of decreasing the linear expansion coefficient of the cured product by adding a large amount of inorganic filler materials into the curable resin composition was used (Patent Document 2).

### PRIOR-ART DOCUMENTS

### Patent Documents

[Patent Document 1] International Publication No. WO 2010/090246
[Patent Document 2] Japanese Patent Publication No. 2004-172443

However, in the method proposed by Patent Document 1, although gelation properties may be imparted to the epoxy resin composition, since a cured product of the epoxy resin composition prepared by compounding the pre-gelatinizing agent is increased in linear expansion coefficient, there was no effect in terms of improvement in the crack resistance.

Meanwhile, in the method proposed by Patent Document 2, although a curable resin composition excellent in crack resistance may be obtained, the viscosity is remarkably reduced due to the rise in temperature for the curing, so high precision coating and pattern forming were difficult.

Therefore, the actual condition is that the prior art has not provided a material that imparts gelation properties to a curable resin composition and imparts crack resistance to a cured product.

### SUMMARY OF THE INVENTION

An object of the invention is to provide a vinyl polymer powder, a curable resin composition containing the vinyl polymer powder and a cured product thereof, and a semiconductor sealing material using the cured product. The vinyl polymer powder has excellent dispersibility in the curable resin composition, and rapidly turns the curable resin composition into a gel state by heating at a predetermined temperature in a short time. Moreover, the vinyl polymer powder decreases the linear expansion coefficient of the obtained cured product, so as to improve crack resistance.

The invention is specified by the following items.

Item (1) is a vinyl polymer powder that includes a vinyl polymer having a glass transition temperature of 120° C. or higher and a mass average molecular weight of 100,000 or more.

Item (2) is the vinyl polymer powder of item (1) which includes 50 mass % or more of a monomer unit with a homopolymer glass transition temperature of 120° C. or higher.

Item (3) is the vinyl polymer powder of item (1) which includes 50 to 98 mass % of a monomer unit having a homopolymer glass transition temperature of 120° C. or higher, and 50 to 2 mass % of other monomer unit.

Item (4) is the vinyl polymer powder of item (2) or (3) which includes 70 mass % or more of a monomer unit having a homopolymer glass transition temperature of 120° C. or higher.

Item (5) is the vinyl polymer powder of any one of items (2) to (4) in which the molar volume of the monomer unit having a homopolymer glass transition temperature of 120° C. or higher is 150 cm³/mol or more.

Item (6) is the vinyl polymer powder of any one of items (2) to (5) in which the monomer unit having a homopolymer glass transition temperature of 120° C. or higher is at least one selected from the group consisting of an alicyclic (meth)acrylate unit, a methacrylic acid unit, a vinyl cyanide monomer unit and a styrene derivative unit.

Item (7) is the vinyl polymer powder of item (6) in which the monomer unit having a homopolymer glass transition temperature of 120° C. or higher is the alicyclic (meth)acrylate unit.

Item (8) is the vinyl polymer powder of item (7) in which the alicyclic (meth)acrylate unit is at least one selected from the group consisting of a dicyclopentanyl methacrylate unit and an isobornyl methacrylate unit.

Item (9) is the vinyl polymer powder of any one of items (3) to (8) in which the other monomer unit is an alkyl (meth)acrylate unit.

Item (10) is the vinyl polymer powder of any one of items (1) to (9) of which the volume average primary particle diameter is 0.2 μm or more and 8 μm or less.

Item (11) is the vinyl polymer powder of any one of items (1) to (10) in which the content of alkali metal ions is 10 ppm or less.

Item (12) is the vinyl polymer powder of any one of items (1) to (11) of which the acid value is 50 mgKOH/g or less.

Item (13) is the vinyl polymer powder of any one of items (1) to (12) in which the particles having a particle diameter of 10 μm or less account for less than 30 volume % of the vinyl polymer powder, and the particles having a particle diameter of 10 μm or less account for 30 volume % or more of the vinyl polymer powder after irradiation of an ultrasonic wave having a frequency of 42 kHz and an output of 40 W for 5 minutes.

Item (14) is a pre-gelatinizing agent for a curable resin, which includes the vinyl polymer powder of items (1) to (13).

Item (15) is a curable resin composition including the vinyl polymer powder of items (1) to (13) and a curable resin.

Item (16) is the curable resin composition of item (15), wherein the curable resin is an epoxy resin.

Item (17) is a cured product obtained by curing the curable resin composition of item (15) or (16).

Item (18) is a semiconductor sealing material using the curable resin composition of tem (15) or (16).

### Effects of the Invention

The vinyl polymer powder of the invention has excellent dispersibility in the curable resin composition, and rapidly turns the curable resin composition into a gel state by heating at a predetermined temperature in a short time. In addition, the vinyl polymer powder decreases the linear expansion coefficient of the obtained cured product, and improves the crack resistance. Moreover, the curable resin composition of the invention may be highly gelatinized by heating at a predetermined temperature in a short time. Moreover, the cured product of the invention has a low linear expansion coefficient, and excellent electrical properties. Therefore, the vinyl polymer powder of the invention is suitable for a pre-gelatinizing agent for a curable resin. In addition, the curable resin composition of the invention and the cured product of the invention are suitable for a semiconductor sealing material.

### DESCRIPTION OF EMBODIMENTS

A vinyl polymer powder of the invention includes a vinyl polymer having a glass transition temperature of 120° C. or higher and a mass average molecular weight of 100,000 or more.

<Glass Transition Temperature>

If the glass transition temperature of the vinyl polymer is 120° C. or higher, the linear expansion coefficient of the cured product obtained by curing the curable resin composition of the invention is decreased. Moreover, in view of decreasing the linear expansion coefficient, the glass transition temperature of the vinyl polymer is preferably 140° C. or higher, more preferably 150° C. or higher, and further more preferably 160° C. or higher. In addition, in terms of forming a gel state highly effectively at a constant temperature, the glass transition temperature of the vinyl polymer is preferably 300° C. or lower, more preferably 280° C. or lower, and especially preferably 250° C. or lower.

In the invention, the glass transition temperature of the vinyl polymer refers to the temperature value obtained by a later-described method for measuring the glass transition temperature.

The glass transition temperature of the vinyl polymer may be well controlled by a commonly used method. For example, the glass transition temperature of the vinyl polymer may be controlled within a desired range by properly selecting the type of the monomer component used for polymerization, the composition ratio of monomer components that constitute the polymer, and the molecular weight of the polymer, etc.

To obtain the vinyl polymer having a glass transition temperature of 120° C. or higher, it is sufficient only to polymerize a monomer mixture containing a monomer having a homopolymer glass transition temperature of 120° C. or higher. The homopolymer glass transition temperature may be a standard analysis value mentioned in “Polymer Data Handbook” edited by the Society of Polymer Science of Japan, etc.

Moreover, in cases where a commercial product of a raw material manufacturer is used as the monomer, the homopolymer glass transition temperature disclosed in a catalog or the like of the manufacturer may be used.

<Mass Average Molecular Weight>

The mass average molecular weight of the vinyl polymer is 100,000 or more. If the mass average molecular weight of the vinyl polymer is 100,000 or more, the vinyl polymer may provide high gelation properties in a small amount, and may suppress flow of the curable resin even at a high temperature. Moreover, in terms of not reducing solubility in the curable resin and forming a sufficient gel state in a short time, the mass average molecular weight of the vinyl polymer is preferably 20,000,000 or less.

In terms of imparting high gelation properties even in cases where the curable resin has an extremely low viscosity, the mass average molecular weight of the vinyl polymer is preferably 400,000 or more, more preferably 600,000 or more, and further more preferably 800,000 or more. In addition, in terms of forming a gel state highly efficiently at a constant temperature, the mass average molecular weight of the vinyl polymer is more preferably 10,000,000 or less, especially preferably 5,000,000 or less, and most preferably 2,000,000 or less.

The mass average molecular weight may be properly adjusted by changing the type of the polymerization initiator, the amount of the polymerization initiator, the polymerization temperature or the amount of the chain transfer agent.

In the invention, the gel state is evaluated by means of the gelation temperature and the gelation performance obtained by the later-described measurement method.

In the invention, the mass average molecular weight refers to a value obtained by the later-described measurement method for mass average molecular weight. In cases where the vinyl polymer powder has an insoluble component, an acetone soluble part is obtained by the later-described method, and the mass average molecular weight of the acetone soluble part is defined as the mass average molecular weight of the vinyl polymer.

<Volume Average Particle Diameter>

The volume average primary particle diameter (Dv) of the vinyl polymer powder of the invention is preferably 0.2 nm or more, and more preferably 0.5 nm or more. If Dv is 0.2 nm or more, the total surface area of the particles is sufficiently reduced, thus having an advantage that the viscosity of the curable resin composition hardly increases.

Moreover, in terms of allowing a fine pitch or thin film to be made, the volume average primary particle diameter (Dv) of the vinyl polymer powder is preferably 8 μm or less, more preferably 5 μm or less, and especially preferably 1.5 μm or less.

The volume average primary particle diameter (Dv) may be properly adjusted by the polymerization method. For example, the Dv is 0.25 μm or less in use of an emulsion polymerization, 1 μm or less in use of a soap-free emulsion polymerization, and 10 μm or less in use of a fine suspension polymerization. In cases where polymerization is performed by an emulsion polymerization method, a further adjustment may be performed by changing the amount of the emulsifier.

There is no limitation on the characteristics or structure of the vinyl polymer powder of the invention as powder. For example, a large number of primary particles obtained in the polymerization may be aggregated to form an aggregation powder (secondary particles), and also a higher order structure. However, in the case of such aggregation powder, it is preferred that the primary particles are loosely combined with one another and slowly aggregated. Accordingly, in the curable resin, the primary particles are fine and uniformly dispersed.

Moreover, in terms of improving the dispersibility in the curable resin, the vinyl polymer powder preferably includes a small number of particles having a small volume average primary particle diameter (Dv) and preferably has good monodispersity.

In the invention, the monodispersity of the vinyl polymer powder is defined as the ratio (Dv/Dn) of the volume average primary particle diameter (Dv) to the number average primary particle diameter (Dn) of the vinyl polymer powder. The Dv/Dn ratio of the vinyl polymer powder is preferably 3.0 or less, more preferably 2.0 or less, and especially preferably 1.5 or less. As the monodispersity of the vinyl polymer powder increases (Dv/Dn gets closer to 1), there is a tendency that the gelation of the curable resin composition proceeds rapidly in a short time and a storage stability of the curable resin composition easily coexists.

<Alkali Metal Ions>

The content of alkali metal ions in the vinyl polymer powder of the invention is preferably 10 ppm or less. If the content of the alkali metal ions in the vinyl polymer powder is 10 ppm or less, the insulating characteristics of the cured product become excellent. The content of the alkali metal ions in the vinyl polymer powder is more preferably 5 ppm or less, and especially preferably 1 ppm or less.

The curable resin composition is applied to various uses, but is especially required to have high electrical properties in the uses in which it is in direct contact with semiconductor wafers. In addition, with reduction in thickness of electronic devices, there are also cases where the presence of a small amount of ionic impurities causes insulation failure. Therefore, if the content of the alkali metal ions is within the above range, the vinyl polymer powder may be applied to a wide range of uses. Moreover, it may also be applied to the uses requiring a large amount of pre-gelatinizing agent.

In the invention, the content of the alkali metal ions in the vinyl polymer powder is the total amount of Na ions and K ions, and refers to the value obtained by the later-described measurement method for the content of alkali metal ions.

<Acid Value>

The acid value of the vinyl polymer powder of the invention is preferably 50 mgKOH/g or less, more preferably 40 mgKOH/g or less, and especially preferably 30 mgKOH/g or less. If the acid value of the vinyl polymer powder is 50 mgKOH/g or less, the insulating characteristics of the cured product become excellent.

In the invention, the acid value of the vinyl polymer powder refers to the value obtained by the later-described measurement method for acid value.

<Sulfate Ions>

The content of sulfate ions (SO₄²⁻) in the vinyl polymer powder of the invention is preferably 20 ppm or less. The curable resin composition for electronic materials are used in an environment in contact with wires or circuit wirings made of metal such as copper or aluminum, and thus if the sulfate ions are left, metal corrosion may occur to be a cause of conduction failure or malfunction. If the content of the sulfate ions in the vinyl polymer powder is 20 ppm or less, the vinyl polymer powder may be applied to a wide range of uses.

To obtain the vinyl polymer of the invention, in a case of polymerizing a vinyl monomer with an emulsion polymerization method or a suspension polymerization method, in addition to a sulfuric acid salt, a sulfate ester or a sulfonic acid compound or the like may be used. There are cases where sulfonic acid ions, sulfinic acid ions and sulfate ester ions contained in these compounds also cause metal corrosion.

Therefore, during the polymerization of the vinyl monomer, it is preferred to decrease the amount of the sulfate ester or sulfonic acid compound or the like used.

<Amount of Acetone Soluble Part>

There is no particular limitation on the amount of the acetone soluble part in the vinyl polymer powder of the invention, and 30 mass % or more is preferred. If the amount of the acetone soluble part in the vinyl polymer powder is 30 mass % or more, the vinyl polymer powder may impart sufficient gelation properties to the curable resin composition, and may suppress flow of the same even at a high temperature.

In terms of imparting high gelation properties even in cases where the curable resin has an extremely low viscosity, the amount of the acetone soluble part in the vinyl polymer powder is preferably 40 mass % or more, especially preferably 50 mass % or more, and most preferably 80 mass % or more. In particular, in a use requiring a low viscosity, it is demanded that high gelation properties be imparted by a small amount of addition. Thus, the more the acetone soluble part, the more readily the vinyl polymer powder may be applied to a wide range of uses.

In the invention, the amount of the acetone soluble part refers to the value obtained by the later-described measurement method for acetone soluble part.

<Polymerization>

The vinyl polymer powder of the invention is produced by, e.g., polymerizing a vinyl polymer capable of radical polymerization, and then recovering from the emulsion the obtained polymer in the powder form.

As the polymerization method for the vinyl polymer, in terms of easily obtaining the particle in a spherical shape and easily controlling particle morphology, an emulsion polymerization method, a soap-free emulsion polymerization method, a swelling polymerization method, a miniemulsion polymerization method, a dispersion polymerization method or a fine suspension polymerization method is preferred. Among them, in terms of easily obtaining a polymer being excellent in dispersibility and having a particle diameter allowing a fine pitch to be made, a soap-free emulsion polymerization method and a fine suspension polymerization method are more preferred, and a soap-free emulsion polymerization method is especially preferred.

In terms of not increasing the viscosity of the curable resin composition and being excellent in fluidity, the vinyl polymer of the invention is preferably particles in a spherical shape.

There is no particular limitation on the internal morphology of the vinyl polymer (primary particles). The structure may be uniform in various factors such as polymer constitution, molecular weight, glass transition temperature and solubility parameter, etc. There are also various other commonly known particle morphologies such as a core-shell structure or a gradient elution structure.

The method of controlling the internal morphology of the vinyl polymer is, for example, a method of forming a multi-structured particle wherein the inner and outer sides of the particle have different solubility parameters or molecular weights. The method is preferred since it easily achieves both the storage stability (pot life) and gelation speed of the curable resin composition.

The method for controlling the internal morphology of the vinyl polymer and having high industrial utility is, e.g., a method of polymerization by sequentially dropping vinyl monomer mixtures of different compositions in a multi-step manner.

The method of determining whether the vinyl polymer has a core-shell structure is, e.g., determining whether both of the following requirements are met: that the particle diameter of a polymer particle sampled during the polymerization is definitely growing, and that the minimum film-forming temperature (MFT) of the polymer particle sampled during the polymerization or the solubility of the same in various solvents is varying. Moreover, for example, the following method is mentioned: a method of observing a section of the vinyl polymer using a transmission electron microscope (TEM) to determine if there is any structure in a concentric circular shape, or a method of observing a section of a freeze-fractured vinyl polymer using a scanning electron microscope (cryo-scanning electron microscope (Cryo-SEM)) to determine if there is any structure in a concentric circular shape.

<Monomer Having a Homopolymer Glass Transition Temperature of ≧120° C.>

A vinyl monomer capable of radical polymerization is used as the vinyl polymer. To obtain the vinyl polymer powder having a glass transition temperature of 120° C. or higher, it is sufficient only to polymerize a monomer mixture containing a monomer having a homopolymer glass transition temperature of 120° C. or higher. Herein, a monomer having a homopolymer glass transition temperature of 300° C. or lower is preferably used, and a monomer having a homopolymer glass transition temperature of 250° C. or lower is more preferably used. By using a monomer having a homopolymer glass transition temperature of 300° C. or lower, a gel state may be formed highly efficiently at a constant temperature.

Examples of vinyl monomer with a homopolymer glass transition temperature of 120° C. or higher include: alicyclic (meth)acrylates, such as dicyclopentenyl acrylate (Tg: 120° C.), dicyclopentenyl methacrylate (Tg: 175° C.), dicyclopentanyl acrylate (Tg: 120° C.), dicyclopentanyl methacrylate (Tg: 175° C.), and isobornyl methacrylate (Tg: 150° C.), etc.; methacrylic acid (Tg: 228° C.); vinyl cyanide monomers, such as acrylonitrile (Tg: 125° C.) and methacrylonitrile (Tg: 120° C.), etc.; and styrene derivatives, such as 2-methylstyrene (Tg: 136° C.), t-butylstyrene (Tg: 149° C.) and 4-t-butylstyrene (Tg: 131° C.), etc. These monomers may be used alone or in combination of two or more.

Among these monomers, a vinyl monomer whose molar volume of monomer unit is 150 cm³/mol or more is preferred. In the invention, the molar volume of the monomer unit may be obtained by the method of Jozef Bicerano (J. Bicerano, “Prediction of Polymer Properties,” 3rd edition, 2002, Marcel Dekker).

Examples of the vinyl monomer whose molar volume of monomer unit is 150 cm³/mol or more include: dicyclopentenyl methacrylate (205 cm³/mol), and isobornyl methacrylate (205 cm³/mol), etc.

Among these monomers, in terms of easy radical polymerization, and easy emulsion polymerization and fine suspension polymerization, alicyclic (meth)acrylates are preferred. In addition, among these monomers, in terms of excellent effects in increasing the homopolymer glass transition temperature and in decreasing the linear expansion coefficient of the cured product, dicyclopentanyl methacrylate and isobornyl methacrylate are preferred.

Besides, in the invention, “(meth)acrylate” refers to acrylate or methacrylate.

In view of the effect of decreasing the linear expansion coefficient of the cured product, the content of the vinyl monomers in the monomer mixture that have a homopolymer glass transition temperature of 120° C. or higher, i.e., the content of the monomer unit in the vinyl polymer constituting the powder, is preferably 50 mass % or more, more preferably 70 mass % or more, especially preferably 80 mass % or more, and most preferably 88 mass % or more. Moreover, when other monomers described below are used, the content of the vinyl monomers having a homopolymer glass transition temperature of 120° C. or higher is preferably 50 to 98 mass %.

<Other Monomers>

In addition to the monomers having a homopolymer glass transition temperature of 120° C. or higher, other monomer may be included in the monomer mixture if necessary, as long as the glass transition temperature of the vinyl polymer powder can be kept within the scope of being 120° C. or higher.

There is no particular limitation on the other monomers as long as they are vinyl monomers capable of radical polymerization.

Examples of the other monomers include: alkyl (meth)acrylates, such as methyl (meth)acrylate, ethyl (meth)acrylate, n-propyl (meth)acrylate, i-propyl (meth)acrylate, n-butyl (meth)acrylate, t-butyl (meth)acrylate, i-butyl (meth)acrylate, n-hexyl (meth)acrylate, n-octyl (meth)acrylate, 2-ethylhexyl (meth)acrylate, cyclohexyl (meth)acrylate, benzyl (meth)acrylate, phenyl (meth)acrylate, nonyl (meth)acrylate, decyl (meth)acrylate, dodecyl (meth)acrylate, and stearyl (meth)acrylate, etc.; aromatic vinyl monomers, such as styrene and α-methylstyrene, etc.; (meth)acrylates containing a functional group, such as 2-hydroxyethyl (meth)acrylate, 2-hydroxypropyl (meth)acrylate, 4-hydroxybutyl (meth)acrylate, glycerol mono(meth)acrylate, and glycidyl (meth)acrylate, etc.; (meth)acrylamide; vinyl monomers, such as vinyl pyridine, vinyl alcohol, vinylimidazole, vinylpyrrolidone, vinyl acetate, and 1-vinylimidazole, etc.; itaconate esters, such as monomethyl itaconate and monoethyl itaconate, etc.; fumarate esters, such as monomethyl fumarate, monoethyl fumarate, monopropyl fumarate, and monobutyl fumarate, etc.; and maleate esters, such as monomethyl maleate, monoethyl maleate, monopropyl maleate, and monobutyl maleate, etc. These monomers may be used alone or in combination of two or more.

Among these monomers, alkyl (meth)acrylates are preferred. Moreover, in terms of easy radical polymerization, and easy emulsion polymerization and fine suspension polymerization, alkyl (meth)acrylates and (meth)acrylates containing a functional group are preferred. In addition, in terms of excellent polymerization stability, alkyl (meth)acrylates having a carbon number of 1 to 4 are preferred; in terms of little reduction in the glass transition temperature of the vinyl polymer powder, alkyl methacrylates having a carbon number of 1 to 4 are more preferred.

The monomer mixture may include a cross-linkable monomer if necessary. Examples of the cross-linkable monomer include: ethylene glycol di(meth)acrylate, propylene glycol di(meth)acrylate, 1,3-butyleneglycol di(meth)acrylate, 1,4-butyleneglycol di(meth)acrylate, allyl (meth)acrylate, triallyl cyanurate, triallyl isocyanurate, divinylbenzene, and polyfunctional (meth)acryl group-modified silicones. These cross-linkable monomers may be used alone or in combination of two or more.

In addition, in view of cases where monomers containing a halogen atom, such as vinyl chloride or vinylidene chloride, cause metal corrosion, no use of cross-linkable monomer is preferred.

In view of the effect of decreasing the linear expansion coefficient of the cured product, the content of monomers other than those with a homopolymer glass transition temperature of 120° C. or higher in the monomer mixture, i.e., the content of the other monomer units in the vinyl polymer constituting the powder, is preferably 50 mass % or less, more preferably 30 mass % or less, further more preferably 20 mass % or less, and most preferably 12 mass % or less. Moreover, in view of the polymerization stability and particle diameter control, 2 mass % or more is preferred, and 5 mass % or more is more preferred.

<Other Components>

In polymerizing the monomer, a polymerization initiator, an emulsifier, a dispersion stabilizer, and a chain-transfer agent may be used.

Examples of the polymerization initiator include: persulfate salts, such as potassium persulfate, sodium persulfate, and ammonium persulfate, etc.; oil-soluble azo compounds, such as azobisisobutyronitrile, 2,2′-azobis(2-methylbutyronitrile), 2,2′-azobis(2,4-dimethylvaleronitrile), 2,2′-azobis(4-methoxy-2,4-dimethylvaleronitrile), 1-1′-azobis(cyclohexane-1-carbonitrile), and dimethyl-2,2′-azobis(2-methylpropionate), etc.; water-soluble azo compounds, such as 4,4′-azobis(4-cyanovaleric acid), 2,2′-azobis{2-methyl-N-[1,1-bis(hydroxymethyl)-2-hydroxyethyl]propionamide}, 2,2′-azobis{2-methyl-N-[2-(2-hydroxyethyl)]propionamide}, 2,2′-azobis{2-methyl-N-[2-(1-hydroxybutyl)]propionamide}, 2,2′-azobis[2-(5-methyl-2-imidazolin-2-yl)propane] and salts thereof, 2,2′-azobis[2-(2-imidazolin-2-yl)propane] and salts thereof, 2,2′-azobis[(2-(3,4,5,6-tetrahydropyrimidin-2-yl)propane] and salts thereof, 2,2′-azobis {2-[1-(2-hydroxyethyl)-2-imidazolin-2-yl]propane} and salts thereof, 2,2′-azobis(2-methylpropionamidine) and salts thereof, 2,2′-azobis(2-methylpropyneamidine) and salts thereof, 2,2′-azobis[N-(2-carboxyethyl)-2-methylpropionamidine] and salts thereof, etc.; and organic peroxides, such as benzoyl peroxide, cumene hydroperoxide, t-butylhydroperoxide, t-butylperoxy-2-ethylhexanoate, t-butylperoxyisobutyrate, lauroyl peroxide, propylbenzene hydroperoxide, Permenta® hydroperoxide, 1,1,3,3-tetramethylbutyl peroxy-2-ethylhexanoate, etc. These polymerization initiators may be used alone or in combination of two or more.

Among them, the polymerization initiators not containing alkali metal ions are preferred, and ammonium persulfate and azo compounds are more preferred. Moreover, it is further more preferred to use an azo compound not containing chloride ions and ammonium persulfate in combination since the combined use reduces the content of the sulfate ions (SO₄²⁻) in the vinyl polymer powder.

Moreover, within a scope not deviating from the purpose of the invention, a redox-type initiator, which is formed by combining a reducing agent, such as sodium formaldehydesulfoxylate, L-ascorbic acid, fructose, dextrose, sorbose, or inositol, etc., with ferrous sulfate, ethylenediaminetetraacetic acid disodium salt and peroxide, may be used.

Examples of the emulsifier include: anionic emulsifiers, cationic emulsifiers, non-ionic emulsifiers, betaine-type emulsifiers, polymeric emulsifiers and reactive emulsifiers.

Examples of the anionic emulsifiers include: alkylsulfonate salts, such as sodium alkylsulfonate, etc.; alkyl sulfate salts, such as sodium lauryl sulfate, ammonium lauryl sulfate, and triethanolamine lauryl sulfate, etc.; alkyl phosphate salts, such as potassium polyoxyethylene alkylphosphate, etc.; alkylbenzene sulfonate salts, such as sodium alkylbenzene sulfonate, sodium dodecylbenzenesulfonate, and sodium alkylnaphthalenesulfonate, etc.; and dialkyl sulfosuccinate salts, such as sodium dialkyl sulfosuccinate, and ammonium dialkyl sulfosuccinate, etc.

Examples of the cationic emulsifiers include: alkyl amine salts, such as stearylamine acetate, coconut amine acetate, tetradecylamine acetate, and octadecylamine acetate, etc.; and quaternary ammonium salts, such as lauryltrimethylammonium chloride, stearyl trimethylammonium chloride, cetyltrimethylammonium chloride, distearyldimethylammonium chloride, and alkylbenzylmethylammonium chloride, etc.

Examples of the non-ionic emulsifiers include: sorbitan fatty acid esters, such as sorbitan monolaurate, sorbitan monopalmitate, sorbitan monostearate, sorbitan tristearate, sorbitan monooleate, sorbitan trioleate, sorbitan monocaprylate, sorbitan monomyristate, and sorbitan monobehenate, etc.; polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan tristearate, polyoxyethylene sorbitan monooleate, and polyoxyethylene sorbitan triisostearate, etc.; polyoxyethylene sorbitol fatty acid esters, such as polyoxyethylene sorbitol tetraoleate, etc.; polyoxyethylene alkyl ethers, such as polyoxyethylene lauryl ether, polyoxyethylene cetyl ether, polyoxyethylene stearyl ether, polyoxyethylene oleyl ether, and polyoxyethylene myristyl ether, etc.; polyoxyethylene alkyl esters, such as polyoxyethylene monolaurate, polyoxyethylene monostearate, and polyoxyethylene monooleate, etc.; and polyoxyalkylene derivatives, such as polyoxyethylene alkylene alkylether, polyoxyethylene distyrenated phenyl ether, polyoxyethylene tribenzylphenylether, and polyoxyethylene polyoxypropylene glycol, etc.

Examples of the betaine-type emulsifiers include: alkyl betaines, such as lauryl betaine and stearyl betaine, etc.; and alkylamine oxides, such as lauryl dimethylamine oxide, etc.

Examples of the polymeric emulsifiers include: polymeric sodium carboxylate, polymeric ammonium polycarboxylate, and polymeric polycarboxylic acid.

Examples of the reactive emulsifiers include: polyoxyalkylene alkenyl ethers, such as polyoxyalkylene alkenyl ether ammonium sulfate, etc.

These emulsifiers may be used alone or in combination of two or more.

Among them, the emulsifiers not containing alkali metal ions are preferred, and dialkyl sulfosuccinate and polyoxyalkylene derivatives are more preferred. In addition, it is more preferred to use dialkyl sulfosuccinate and polyoxyalkylene derivatives in combination since the amount of the sulfonic acid compound and so on used may be decreased.

Examples of the dispersion stabilizer include: poorly water-soluble inorganic salts, such as calcium phosphate, calcium carbonate, aluminum hydroxide, starch and silica, etc.; non-ionic polymeric compounds, such as polyvinyl alcohol, polyethylene oxide, and cellulose derivatives, etc.; and anionic polymeric compounds, such as polyacrylic acid and salts thereof, polymethacrylic acid and salts thereof, and copolymers of a methacrylate and methacrylic acid or a salt thereof, etc. Among them, in terms of excellent electrical properties, non-ionic polymeric compounds are preferred. Moreover, in view of also having polymerization stability, the dispersion stabilizers may be used in combination of two or more depending on purposes.

In performing polymerization for obtaining the vinyl polymer of the invention, a chain-transfer agent may be used if necessary.

Examples of the chain-transfer agent include: mercaptans, such as n-dodecyl mercaptan, t-dodecyl mercaptan, n-octyl mercaptan, t-octyl mercaptan, n-tetradecyl mercaptan, n-hexyl mercaptan, and n-butyl mercaptan, etc.; halogen compounds, such as carbon tetrachloride, and ethylene bromide, etc.; and α-methyl styrene dimer.

These chain-transfer agents may be used alone or in combination of two or more.

<Powder Recovery>

The vinyl polymer powder of the invention is produced by, for example, recovering from the emulsion the obtained vinyl polymer in form of a powder.

A well-known powdering method may be used as the method of powdering the emulsion of the vinyl polymer. For example, a spray drying method, a freeze drying method, and a coagulation method may be used. Among these powdering methods, in terms of excellent dispersibility of the vinyl polymer in resin, a spray drying method is preferred.

The spray drying method is a method in which a latex is sprayed in the form of micro droplets and is dried with a hot wind. The method of generating micro droplets is, for example: a rotating disk method, a pressure nozzle method, a two-fluid nozzle method, or a pressurized two-fluid nozzle method. There is no particular limitation on the capacity of the dryer, and any capacity from small scale as used in a laboratory to large scale as used industrially may be employed. In the dryer, there is eithert no particular limitation on the location of the inlet portion that is a feeding section of heated gas for drying, or on the location of the outlet portion that is an exhaust port of the heated gas for drying and dry powder, and the locations may have the same conditions as those of usually used spray drying apparatuses. In terms of excellent dispersibility of the vinyl polymer powder in the obtained curable resin composition, the temperature (inlet temperature) of the hot wind guided into the apparatus, i.e., the maximum temperature capable of being in contact with the vinyl polymer, is preferably 100 to 200° C., and more preferably 120 to 180° C.

During the spray drying, the latex of the vinyl polymer may be used alone, or a mixture of a plurality of kinds of latex may be used. In order to improve powder properties such as blocking in spray drying, bulk specific gravity, etc., an inorganic filler such as silica, talc or calcium carbonate, etc., or polyacrylate, polyvinyl alcohol, or polyacrylamide, etc., may be added thereto.

Moreover, an antioxidant or additive or the like may be added for the spray drying as required.

<Powder Crushing Properties>

In the vinyl polymer powder of the invention, it is preferred that the particles having a particle diameter of 10 μm or less account for a proportion of less than 30 volume %. In terms of good handling ability, 20 volume % or less is preferred. Here, the so-called particle diameter of the vinyl polymer powder refers to the particle diameter of an aggregate obtained using a spray drying method or a wet coagulation method or the like. At this moment, the aggregate is formed by aggregating a large number of the primary particles of the vinyl polymer powder together.

The vinyl polymer powder of the invention is preferably in a state that the primary particles are loosely combined with one another and slowly aggregated. It is preferred that the particles having a particle diameter of 10 μm or less account for 30 volume % or more after irradiation of an ultrasonic wave having a frequency of 42 kHz and an output of 40 W for 5 minutes. In addition, it is preferred that after the ultrasonic wave irradiation, the proportion of the particles having a particle diameter of 10 μm or less is increased by 10 volume % compared to that before the ultrasonic wave irradiation.

The above ultrasonic wave irradiation is performed on the obtained vinyl polymer powder after it is diluted with ion-exchanged water. For example, after ultrasonic wave irradiation for 3 minutes using a laser diffraction/scattering particle diameter distribution measurement apparatus (SALD-7100, by Shimadzu Corporation), the proportion of the particles having a particle diameter of 10 μm or less is measured on a volumetric basis.

The sample concentration of the vinyl polymer powder is properly adjusted to be in a proper range in a scattered light intensity monitor attached to the apparatus.

<Curable Resin>

The vinyl polymer powder of the invention may be used by being added to, for example, a curable resin. Examples of the curable resin include thermosetting resins and active energy line-curable resins.

Examples of the thermosetting resins include: epoxy resins, phenolic resins, melamine resins, urea resins, oxetanic resins, unsaturated polyester resins, alkyd resins, polyurethane resins, acrylic resins and polyimide resins. These may be used alone or in combination of two or more.

Examples of the active energy line-curable resins include resins curably by irradiation with an ultraviolet ray or electron beam, such as active energy line-curable acrylic resins, active energy line-curable epoxy resins and active energy line-curable oxetanic resins.

Moreover, in the invention, depending on purposes, a mixed curable (dual cure) resin of thermosetting and active energy line-curable resins may be used as the curable resin.

Among them, as the curable resin, in terms of high insulation, excellent electrical properties and being suitable for the field of electronic materials, epoxy resins, phenolic resins, polyimide resins and oxetanic resins are preferred.

Examples of the epoxy resins include: bisphenol A-type epoxy resins, such as JER827, JER828, JER834 (produced by Mitsubishi Chemical Corporation), and RE-310S (by Nippon Kayaku Co., Ltd.), etc.; bisphenol F-type epoxy resins, such as JER806L (by Mitsubishi Chemical Corporation), and RE303S-L (by Nippon Kayaku Co., Ltd.), etc.; naphthalene-type epoxy resins, such as HP-4032 and HP-4032D (by Dainippon Ink and Chemicals), etc.; biphenyl-type epoxy resins, such as NC-3000 (by Nippon Kayaku Co., Ltd.) and YX4000 (by Mitsubishi Chemical Corporation), etc.; crystalline epoxy resins, such as YDC-1312, YSLV-80XY and YSLV-120TE (by Tohto Kasei Co., Ltd.), etc.; hydrogenated bisphenol A-type epoxy resins, such as YX8000 (by Mitsubishi Chemical Corporation); alicyclic epoxy resins, such as CEL2021P (by Daicel Chemical Industries, Ltd.), etc.; and heat-resistant epoxy resins, such as EPPN-501H, EPPN-501HY and EPPN-502H (by Nippon Kayaku Co., Ltd.), etc.

In addition, other examples include: bisphenol AD-type epoxy resins, bisphenol E-type epoxy resins, dicyclopentadiene-type epoxy resins, phenol novolac-type epoxy resins, cresol novolac-type epoxy resins, brominated epoxy resins, and glycidylamine-type epoxy resins.

In addition, examples of the epoxy resins also include: prepolymers of the above epoxy resins; copolymers of the above epoxy resins and other polymers, such as polyether-modified epoxy resins and silicone-modified epoxy resins; and epoxy resins having a part substituted with a reactive diluent having an epoxy group.

Examples of the reactive diluent include: monoglycidyl compounds, such as resorcin glycidyl ether, t-butyl phenyl glycidyl ether, 2-ethylhexyl glycidyl ether, allyl glycidyl ether, phenyl glycidyl ether, 3-glycidoxy propyl trimethoxysilane, 3-glycidoxy propyl methyl dimethoxysilane, 1-(3-glycidoxy propyl)-1,1,3,3,3-pentamethylsiloxane, and N-glycidyl-N,N-bis[3-(trimethoxysilyl)propyl]amine, etc.; diglycidyl compounds, such as neopentylglycol diglycidyl ether, 1,6-hexanediol diglycidyl ether, and propylene glycol diglycidyl ether, etc.; and monocycloaliphatic epoxy compounds, such as 2-(3,4-epoxy cyclohexyl)ethyl trimethoxysilane, etc.

These epoxy resins may be used alone or in combination of two or more.

In the invention, as the epoxy resin, in terms of imparting gelation properties to the epoxy resin composition, the following resin is preferred: an epoxy resin being in a liquid state at normal temperature; or a resin including, as a main component, an epoxy resin which is in a solid state at normal temperature but liquefy during heating before the curing is sufficiently performed.

In addition, in cases where the epoxy resin composition of the invention is used as a liquid sealing material, examples of preferred epoxy resins include: bisphenol A-type epoxy resins, hydrogenated bisphenol A-type epoxy resins, bisphenol F-type epoxy resins, bisphenol S-type epoxy resins, 3,3′,5,5′-tetramethyl-4,4′-dihydroxy diphenylmethane diglycidyl ether-type epoxy resins, 3,3′,5,5′-tetramethyl-4,4′-dihydroxybiphenyl diglycidyl ether-type epoxy resins, 4,4′-dihydroxybiphenyl diglycidyl ether-type epoxy resins, 1,6-dihydroxynaphthalene-type epoxy resins, phenol novolac-type epoxy resins, cresol novolac-type epoxy resins, brominated bisphenol-A type epoxy resins, brominated cresol novolac-type epoxy resins, and bisphenol-D type epoxy resins.

<Curable Resin Composition>

The curable resin composition of the invention includes the aforementioned vinyl polymer powder and a curable resin.

The amount of the vinyl polymer powder mixed in the curable resin composition is preferably 1 mass % or more, more preferably 3 mass % or more, especially preferably 5 mass % or more, and most preferably 10 mass % or more. If the amount of the vinyl polymer powder mixed is 1 mass % or more, a sufficient gel state may be realized, and the likelihood of exudation or pattern disturbance, etc. due to uses and processing methods may be suppressed. In addition, the amount of the vinyl polymer powder mixed is preferably 50 mass % or less, and more preferably 30 mass % or less. If the amount of the vinyl polymer powder mixed is 50 mass % or less, paste viscosity of the curable resin composition is suppressed from increasing, and the likelihood of decrease in processibility and operability may be suppressed depending on uses.

In addition, to exhibit desired gelation properties, a plurality of kinds of vinyl polymer powders having different gelation temperatures may be used in combination.

Various additives may be mixed in the curable resin composition of the invention within a range not impairing the effects of the invention.

Examples of the additives include: conductive fillers, such as silver powder, gold powder, nickel powder, and copper powder, etc.; insulating fillers, such as aluminum nitride, calcium carbonate, silica, and alumina, etc.; thixotropy imparting agents, flow improvers, flame retardants, thermostabilizers, antioxidants, ultraviolet absorbers, ion adsorbing bodies, coupling agents, release agents and stress relaxing agents.

The flame retardant, if within a scope not deviating from the purpose of the invention, is exemplified by well-known flame retardants such as phosphorus flame retardants, halogen-based flame retardants, inorganic flame retardants, etc.

Examples of the thermostabilizer include: phenolic antioxidants, sulfur-based antioxidants and phosphorus antioxidants. Each of the antioxidants may be used alone. Nevertheless, it is preferred that two or more thereof are used in combination, such as phenolic and sulfur-based ones, or phenolic and phosphorus ones.

A well-known mixing apparatus may be used in preparing the curable resin composition of the invention. The mixing apparatus for obtaining the curable resin composition is, for example, a Raikai mixer, an attritor, a planetary mixer, a dissolver, a three-roll mill, a ball mill and a bead mill. These may be used alone or in combination of two or more.

In cases where the additive and so on are mixed in the curable resin composition of the invention, there is no particular limitation on the order of mixing. However, in order to sufficiently exhibit the effects of the invention, the mixing of the vinyl polymer powder is preferably performed as late as possible. In addition, in cases where a temperature in the system rises due to shear heating resulting from the mixing, it is preferred to make an effort to prevent the temperature from rising during the mixing.

The curable resin composition of the invention is applicable to a variety of uses as follows: liquid sealing materials, such as underfilling materials for primary mounting, underfilling materials for secondary mounting, and glob top materials in wire bonding, etc.; sealing sheets for collective sealing of various chips on a substrate; pre-dispensing type underfilling materials; sealing sheets for collective sealing at a wafer level; adhesion layers for three-layered copper clad laminate; adhesion layers, such as die bond films, die attach films, interlayer insulating films, and cover-lay films, etc.; adhesive pastes, such as die bond pastes, interlayer insulating pastes, conductive pastes, and anisotropic conductive pastes, etc.; sealing materials of light-emitting diode; optical adhesives; sealing materials of various flat panel displays such as liquid crystal and organic electroluminescence (EL) displays, etc.

<Cured Product>

In the invention, in cases where an epoxy resin is used as the curable resin in the curable resin composition, for example, the epoxy resin may be cured by a curing agent such as an anhydride, an amine compound or a phenol compound. The curing ability and cured product characteristics of the epoxy resin may be adjusted by use of the curing agent. In particular, in cases where an anhydride is used as the curing agent, the heat resistance or chemical resistance of the cured product is improved, which is thus preferred.

Examples of the anhydride include: phthalic anhydride, methyl tetrahydrophthalic anhydride, methyl hexahydrophthalic anhydride, hexahydrophthalic anhydride, tetrahydrophthalic anhydride, trialkyl tetrahydrophthalic anhydride, methyl himic anhydride, methylcyclohexene tetracarboxylic anhydride, trimellitic anhydride, pyromellitic dianhydride, benzophenone tetracarboxylic anhydride, ethyleneglycol bistrimellitate, glycerol tristrimellitate, dodecenyl succinic anhydride, polyazelaic polyanhydride, and poly(ethyloctadecanedioic acid) anhydride. Among them, methyl hexahydrophthalic anhydride and hexahydrophthalic anhydride are preferred for uses requiring weather resistance, light resistance, heat resistance and so on.

Examples of the amine compound include: aliphatic polyamines, such as ethylenediamine, diethylenetriamine, triethylenetetramine, tetraethylenepentamine, hexamethylene diamine, trimethyl hexamethylene diamine, m-xylenediamine, 2-methyl pentamethylenediamine, and diethylaminopropyl amine, etc.; alicyclic polyamines, such as isophorone diamine, 1,3-bisaminomethylcyclohexane, methylene biscyclohexanamine, norbornenediamine, 1,2-diaminocyclohexane, bis(4-amino-3-methyldicyclohexyl)methane, diaminodicyclohexylmethane, 2,5(2,6)-bis(aminomethyl)bicyclo[2,2,1]heptane, etc.; aromatic polyamines, such as diaminodiethyldiphenylmethane, diaminophenylmethane, diaminodiphenylsulphone, diaminodiphenyl methane, m-phenylenediamine, diaminodiethyltoluene, etc.

For uses requiring weather resistance, light resistance and heat resistance, etc., 2,5(2,6)-bis(aminomethyl)bicyclo[2,2,1]heptane and isophorone diamine are preferred. These may be used alone or in combination of two or more.

Examples of the phenol compound include: phenol novolac resin, cresol novolac resin, bisphenol A, bisphenol F, bisphenol AD, and diallyl derivatives of these bisphenols. Among them, in terms of excellent mechanical strength and curing ability, bisphenol A is preferred. These may be used alone or in combination of two or more.

In terms of excellent heat resistance and curing ability of the cured product, the amount of the curing agent used is preferably 20 to 120 mass parts, and more preferably 60 to 110 mass parts, relative to 100 mass parts of the epoxy resin. The amount of the curing agent used is defined in terms of equivalence ratio. In the case of anhydride, the amount of anhydride group per 1 equivalent of epoxy group is preferably 0.7 to 1.3 equivalents, and more preferably approximately 0.8 to 1.1 equivalents. In the case of amine compound, the amount of active hydrogen per 1 equivalent of epoxy group is preferably 0.3 to 1.4 equivalents, and more preferably approximately 0.4 to 1.2 equivalents. In the case of phenol compound, the amount of active hydrogen per 1 equivalent of epoxy group is preferably 0.3 to 0.7 equivalent, and more preferably approximately 0.4 to 0.6 equivalent.

In the invention, in curing the epoxy resin, a curing accelerator, a latent curing agent or the like may be used if necessary.

A well-known curing accelerator applied as a thermosetting catalyst for epoxy resin may be used as the curing accelerator. Examples thereof include: imidazole compounds, such as 2-methylimidazole, and 2-ethyl-4-methylimidazole, etc.; adducts of imidazole compounds and epoxy resins; organophosphorus compounds, such as triphenylphosphine, etc.; borates, such as tetraphenylphosphine tetraphenylborate, etc.; and diazabicycloundecene (DBU). These may be used alone or in combination of two or more.

In the use of the curing accelerator, the curing accelerator is usually added in an amount of 0.1 to 8 mass parts, and preferably 0.5 to 6 mass parts, relative to 100 mass parts of the epoxy resin.

Examples of the latent curing agent include: dicyandiamide, carbohydrazide, oxalic dihydrazide, malonic acid dihydrazide, succinic acid dihydrazide, imino diacetic acid dihydrazide, adipic acid dihydrazide, pimelic acid dihydrazide, suberic acid dihydrazide, azelaic acid dihydrazide, sebacic acid dihydrazide, dodecane dihydrazide, hexadecane dihydrazide, maleic acid dihydrazide, fumaric acid dihydrazide, diglycolic acid dihydrazide, tartaric acid dihydrazide, malic acid dihydrazide, isophthalic acid dihydrazide, terephthalic acid dihydrazide, 2,6-naphthoic acid dihydrazide, 4,4′-bisbenzene dihydrazide, 1,4-naphthoic acid dihydrazide, Amicure VDH and Amicure UDH (both trade names, produced by Ajinomoto Co., Inc.), organic acid hydrazides such as citric acid trihydrazide, and various amine adduct compounds. These may be used alone or in combination of two or more.

In the invention, in cases where an oxetanic resin is used as the curable resin in the curable resin composition, for example, the oxetanic resin may be cured by mixing with the curing agent such as an anhydride, or with a curing catalyst that initiates ring opening and polymerization of an oxetane ring by heat. Examples of the oxetanic resin include: EHO, OXBP, OXMA, and OXTP (produced by Ube Industries, Ltd.).

The amount of the curing agent or curing catalyst used is the same as that in the case of epoxy resin. In addition, the oxetanic resin may be used in combination with the epoxy resin.

The cured product of the invention is obtained by curing the curable resin composition.

In cases where a thermosetting resin is used as the curing resin, the curing conditions are, for example, at 80 to 180° C. for 10 minutes to 5 hours.

In addition, in cases where an active energy line-curable resin is used as the curable resin, the active energy line used is, for example, an electron beam, an ultraviolet ray, a gamma ray and an infrared ray. The curing conditions for the active energy line include the following. In cases where an ultraviolet ray is used for curing, a well-known ultraviolet irradiation apparatus provided with a high-pressure mercury lamp, an excimer lamp, a metal halide lamp, etc. may be used.

The amount of ultraviolet irradiation is approximately 50 to 1,000 mJ/cm². In cases where an electron beam is used for curing, a well-known electron beam irradiation apparatus may be used, and the amount of electron beam irradiation is approximately 10 to 100 kGy.

### EXAMPLES

The invention is hereinafter described specifically with reference to examples, but is not limited to these examples. In the following, “part” means “mass part.”

Evaluations in the present examples were performed by the following methods.

(1) Emulsion Particle Diameter and Monodispersity

The vinyl polymer emulsion was diluted with ion-exchanged water, and then the volume average primary particle diameter (Dv) and the number average primary particle (Dn), as the emulsion particle diameter, were measured using a laser diffraction/scattering particle diameter distribution measurement apparatus (“SALD-7100” made by Shimadzu Corporation).

The refractive index was calculated from the addition monomer composition.

In all cases, the median particle diameter was taken as the mean size. Moreover, the monodispersity (Dv/Dn) was obtained by the values of Dv and Dn.

The sample concentration of the vinyl polymer emulsion was properly adjusted to be in a proper range in a scattered light intensity monitor attached to the apparatus.

(2) Acetone Soluble Part

1 g of the vinyl polymer powder was dissolved in 50 g of acetone, and the resultant was refluxed and extracted at 70° C. for 6 hours, followed by centrifugal separation at 14,000 rpm at 4° C. for 30 minutes by means of a centrifugal separator (“CRG SERIES” made by Hitachi, Ltd.). The separated acetone soluble part was removed through decantation. The acetone insoluble part was dried at 50° C. for 24 hours by a vacuum dryer, and the mass thereof was measured. The acetone soluble part (mass %) was calculated using the following formula.

(Acetone soluble part)=(1−mass of acetone insoluble part)×100.

(3) Molecular Weight

The mass average molecular weight (Mw) of the vinyl polymer was measured using gel permeation chromatography under the following conditions. In addition, the number average molecular weight (Mn) was also measured.

Apparatus: HLC8220 made by Tosoh Corporation

Column. TSKgel Super HZM-M (inner diameter 4.6 mm×length 15 cm) made by Tosoh Corporation; number of columns: 4; exclusion limit: 4×10⁶

Temperature: 40° C.

Carrier liquid: tetrahydrofuran

Flow rate: 0.35 ml/min

Sample concentration: 0.1 mass %

Sample injection amount: 10 μl

Standard: polystyrene.

(4) Content of Alkali Metal Ions

An amount of 20 g of the vinyl polymer powder were taken into a glass pressure resistant container, and 200 ml of ion-exchanged water was added thereto using a measuring cylinder. After being covered with a lid, the resultant was strongly shaken to be mixed and dispersed uniformly, thereby obtaining a dispersion liquid of the vinyl polymer powder. After that, the obtained dispersion liquid was left at rest in a Geer oven at 95° C. for 20 hours to extract the ion components in the vinyl polymer powder.

Next, the glass container was removed from the oven and cooled. Then the dispersion liquid was filtered using a membrane filter (made by Advantec Toyo Kaisha, Ltd., model no.: A020A025A) made of 0.2 nm of cellulose-mixed ester. 100 ml of the filtered liquid was used to measure the content of alkali metal ions in the vinyl polymer powder. Moreover, the content of alkali metal ions is obtained by measuring the total amount of Na ions and K ions.

Inductively coupled plasma (ICP) emission spectrometer: IRIS “Intrepid II XSP” made by Thermo Electron Corporation

Quantitative method: absolute calibration curve method by use of concentration-known samples (4 points of 0 ppm, 0.1 ppm, 1 ppm and 10 ppm)

Measurement wavelength: Na: 589.5 nm; and K: 766.4 nm.

(5) Glass Transition Temperature (Tg)

The glass transition temperature (Tg) of the vinyl polymer was measured using “Diamond-DSC” made by PerkinElmer, Inc. according to the JIS (Japanese Industrial Standards)-K7121. In the 2nd-run, a numerical value of the midpoint glass transition temperature was taken as Tg.

Sample amount: 10 mg

Rate of temperature rise: 5° C./min

Temperature range: 0 to 200° C. (temperature rise, cooling, temperature rise)

Environmental conditions: under nitrogen gas flow.

(6) Acid Value

1 g of the vinyl polymer powder was dissolved in 100 ml of a solvent (acetone/ethanol=50/50 volume %). The resultant was titrated with a 0.2 Normality (N) potassium hydroxide (KOH)-ethanol solution to neutralize 1 g of the vinyl polymer powder. The mg number (acid value) of KOH required therefor was calculated using the following formula (1).

Acid value (mgKOH/g)=A×0.2×f×56.1/mass (g) of the vinyl polymer powder (1)

In the formula, A is defined as a titration amount (ml), and f is defined as a titer of the potassium hydroxide solution.

(7) Powder Crushing Properties

The vinyl polymer powder was diluted with ion-exchanged water, and then the proportion of particles of 10 μm or less before and after ultrasonic wave irradiation (frequency: 42 kHz; output: 40 W; irradiation for 3 minutes) was measured on a volumetric basis using a laser diffraction/scattering particle diameter distribution measurement apparatus (“SALD-7100” made by Shimadzu Corporation).

(8) Dispersibility

The state of dispersion of the vinyl polymer powder in an epoxy resin composition was measured using a fineness gauge according to the JIS K-5600, and the dispersibility was evaluated based on the following standard.

⊚: 2 μm or less

∘: more than 2 μm and not more than 10 μm

If the dispersion state of the vinyl polymer powder in the epoxy resin composition is 10 μm or less, it is possible to allow a fine pitch or a thin film to be made.

(9) Gelation Temperature

The temperature dependence of viscoelasticity of the epoxy resin composition was measured using a dynamic viscoelasticity measurement apparatus (“Rheosol G-3000” made by UBM, parallel plate diameter: 40 mm, gap: 0.4 mm, frequency: 1 Hz, twist angle: 1 degree) under the conditions of a starting temperature of 40° C., an ending temperature of 200° C. and a rate of temperature rise rate of 4° C./min.

Moreover, a ratio (G″/G′=tan δ) of storage elastic modulus G′ to loss elastic modulus G″ was 10 or more at a starting point of measurement. When it became less than 10, it was determined that gelation had proceeded, and the temperature at which tan δ=10 was defined as the gelation temperature.

(10) Gelation Performance

In the aforementioned measurement of gelation temperature of the epoxy resin composition, the storage elastic modulus G′ at a temperature lower than the gelation temperature by 20° C. was designated G′_{A}, and the storage elastic modulus G′ at a temperature higher than the gelation temperature by 20° C. was designated G′_{B} (arrival elastic modulus), and the ratio thereof (G′_{B}/G′_{A}) was obtained to evaluate the gelation performance based on the following standard.

∘: G′_{B}/G′_{A} is 100 or more

Δ: G′_{B}/G′_{A} is less than 100.

If G′_{B}/G′_{A} is 100 or more, flow of curable resin may be suppressed even at a high temperature.

(11) Linear Expansion Coefficient

A test piece (having a length of 7 mm, a width of 7 mm and a thickness of 3 mm) of the cured product of the epoxy resin composition was annealed at 180° C. for 6 hours, followed by humidity conditioning at a temperature of 23° C. and a humidity of 50% for 24 hours. According to a critical point of a linear expansion curve measured using “TMA/SS6100” (made by Seiko Instruments Inc.) under the conditions of a rate of temperature rise of 4° C./min and a load of 10 mN, the glass transition temperature was obtained.

Moreover, according to the slope of the linear expansion curve at the temperatures equal to or lower than the glass transition temperature, and the slope of the linear expansion curve at the temperatures equal to or more than the glass transition temperature, respective mean linear expansion coefficients (the former is hereinafter referred to as α1, and the latter as α2) were obtained.

(12) Relative Dielectric Constant

A test piece (having a length of 30 mm, a width of 30 mm and a thickness of 3 mm) of the cured product of the epoxy resin composition was annealed at 180° C. for 6 hours, followed by humidity conditioning at a temperature of 23° C. and a humidity of 50% for 24 hours. A value of the relative dielectric constant at a frequency of 1 GHz was measured using a dielectric constant measurement apparatus (“4291B RF impedance/material analyzer” made by Agilent Technologies), an electrode for dielectric constant measurement (“16453A” made by Agilent Technologies), and a micrometer (made by Mitutoyo Corporation), and evaluation thereof was performed based on the following indicators.

∘: 2.9 or less

Δ: more than 2.9 but not more than 3.0

x: more than 3.0

If the relative dielectric constant is 3.0 or less, the insulation is excellent, which is suitable for the field of electronic materials.

(13) Dielectric Loss Tangent

A test piece (having a length of 30 mm, a width of 30 mm and a thickness of 3 mm) of the cured product of the epoxy resin composition was annealed at 180° C. for 6 hours, followed by humidity conditioning at a temperature of 23° C. and a humidity of 50% for 24 hours. A value of the dielectric loss tangent at a frequency of 1 GHz was measured using a dielectric constant measurement apparatus (“4291B RF impedance/material analyzer” made by Agilent Technologies), an electrode for dielectric constant measurement (“16453A” made by Agilent Technologies), and a micrometer (made by Mitutoyo Corporation), and evaluation thereof was performed based on the following indicators.

∘: 0.010 or less

x: more than 0.010

[Preparation of Vinyl Polymers (1) to (7)]

In accordance with the following Examples 1 to 5 and Comparative Examples 1 and 2, vinyl polymer powders (1) to (7) were prepared. The following materials were used in Examples 1 to 5 and Comparative Examples 1 and 2.

Methyl methacrylate: produced by Mitsubishi Rayon Co., Ltd., trade name: “Acryester M”

N-butyl methacrylate: produced by Mitsubishi Rayon Co., Ltd., trade name: “Acryester B”

Dicyclopentanyl methacrylate: produced by Hitachi Chemical Co., Ltd., trade name: “FA-513M”

Isobornyl methacrylate: produced by Mitsubishi Rayon Co., Ltd., trade name: “Acryester IBX”

Methacrylic acid: produced by Mitsubishi Rayon Co., Ltd., trade name: “Acryester MAA”

Ammonium di-2-ethylhexylsulfosuccinate: produced by TOHO Chemical Industry Co., Ltd., trade name: “Rikacol M-300”

1,1,3,3-tetramethylbutyl peroxy-2-ethylhexanoate: produced by NOF CORPORATION, trade name: “PEROCTA O”

### Example 1

### Production of Vinyl Polymer Powder (1)

78.00 parts of ion-exchanged water, 2.80 parts of methyl methacrylate and 2.20 parts of n-butyl methacrylate were put into a separable flask including a maxblend mixer, a reflux cooling pipe, a temperature control apparatus, a drop pump and a nitrogen introduction pipe. The resultant was stirred at 120 rpm while being subjected to bubbling with nitrogen gas for 30 minutes.

Then, the temperature was raised to 80° C. in a nitrogen atmosphere, and then a previously prepared aqueous solution of 0.04 part of ammonium persulfate and 2.00 parts of ion-exchanged water was put at once in the separable flask and the resultant was maintained for 60 minutes to form seed particles.

A mixture obtained by performing emulsification of 65.30 parts of dicyclopentanyl methacrylate, 29.70 parts of methyl methacrylate, 0.30 part of ammonium di-2-ethylhexylsulfosuccinate, and 50.00 parts of ion-exchanged water using a homogenizer (“Ultra-Turrax T-25” made by IKA Japan K.K., 25,000 rpm) was dripped into the flask for formation of the aforementioned seed particles in 300 minutes, and the resultant was maintained for 1 hour to complete polymerization. The result of the evaluation of the emulsion particle diameter of the obtained vinyl polymer emulsion is shown in Table 1.

The obtained vinyl polymer emulsion was subjected to spray drying using an L-8 type spray dryer made by Ohkawara Kakohki Co., Ltd. under the following conditions to obtain a vinyl polymer powder (1). The result of the evaluation of the acetone soluble part, the molecular weight (Mw and Mn), the content of alkali metal ions, the glass transition temperature (Tg), the acid value and the powder crushing properties of the obtained vinyl polymer powder is shown in Table 1.

[Spray Drying Conditions]

Type of spraying: rotating disk type

Disk rotation speed: 25,000 rpm

Temperature of hot wind:

Inlet temperature: 145° C.

Outlet temperature: 65° C.

### Examples 2 to 4, Comparative Examples 1 and 2

### Production of Vinyl Polymer Powders (2), (3), (4), (6) and (7)

Except that the material composition shown in Table 1 was used, vinyl polymer powders (2), (3), (4), (6) and (7) were obtained in the same manner as in Example 1. The result of the evaluation of the emulsion particle diameter of the obtained polymer emulsion is shown in Table 1. The result of the evaluation of the acetone soluble part, the molecular weight (Mw and Mn), the content of alkali metal ions, the glass transition temperature (Tg), the acid value and the powder crushing properties of the obtained vinyl polymer powder is shown in Table 1.

### Example 5

### Production of Vinyl Polymer Powder (5)

140.00 parts of ion-exchanged water were put into a separable flask including a maxblend mixer, a reflux cooling pipe, a temperature control apparatus, a drop pump and a nitrogen introduction pipe. The resultant was stirred at 120 rpm while being subjected to bubbling with nitrogen gas for 30 minutes, and then its temperature was raised to 80° C. in a nitrogen atmosphere.

Next, a mixture obtained by performing emulsification of 100.00 parts of dicyclopentanyl methacrylate, 0.30 part of ammonium di-2-ethylhexylsulfosuccinate, 0.20 part of “PEROCTA 0,” and 50.00 parts of ion-exchanged water using a homogenizer (“Ultra-Turrax T-25” made by IKA Japan K.K., 25,000 rpm) was put at once in a reaction vessel and maintained for 300 minutes, thereby obtaining a vinyl polymer emulsion. The result of the evaluation of the particle diameter of the obtained vinyl polymer emulsion is shown in Table 1.

The obtained vinyl polymer emulsion was subjected to spray drying in the same manner as in Example 1, thereby obtaining the vinyl polymer powder (5). The result of the evaluation of the acetone soluble part, the molecular weight (Mw and Mn), the content of alkali metal ions, the glass transition temperature (Tg), the acid value and the powder crushing properties of the obtained vinyl polymer powder is shown in Table 1.

TABLE 1

| | | | | | | | | Comparative | Comparative |
|---|---|---|---|---|---|---|---|---|---|
| | | | Example 1 | Example 2 | Example 3 | Example 4 | Example 5 | Example 1 | Example 2 |
| Monomer | Seed | MMA | 2.80 | 2.80 | 2.80 | 2.80 | | 2.80 | 2.80 |
| mixture | polymerization | nBMA | 2.20 | 2.20 | 2.20 | 2.20 | | 2.20 | 2.20 |
| (mass | FA-513M | | 65.30 | 85.00 | 90.00 | | 100.00 | | |
| part) | IBXMA | | | | | 85.00 | | | |
| | MMA | | 29.70 | 10.00 | 5.00 | 10.00 | | 95.00 | 79.20 |
| | n-BMA | | | | | | | | 5.80 |
| | MAA | | | | | | | | 10.00 |

| Vinyl polymer powder | | (1) | (2) | (3) | (4) | (5) | (6) | (7) |
|---|---|---|---|---|---|---|---|---|
| Emulsion | Volume average primary | 0.62 | 0.605 | 0.625 | 0.619 | 2.0 | 0.62 | 0.605 |
| particle | particle diameter Dv (μm) | | | | | | | |
| diameter | Number average primary | 0.564 | 0.545 | 0.565 | 0.563 | 1.25 | 0.565 | 0.555 |
| | particle diameter Dn (μm) | | | | | | | |
| | Monodispersity (Dv/Dn) | 1.10 | 1.11 | 1.11 | 1.10 | 1.60 | 1.10 | 1.09 |
| Acetone souble part (%) | | >98 | >98 | >98 | >98 | >98 | >98 | >98 |
| Molecular | Mw | 92 | 88 | 81 | 78 | 110 | 87 | 85 |
| weight | Mn | 26 | 30 | 27 | 25 | 27 | 33 | 34 |
| (ten | | | | | | | | |
| thousand) | | | | | | | | |

| Content of alkali metal ions (ppm) | | <1 | <1 | <1 | <1 | <1 | <1 | <1 |
|---|---|---|---|---|---|---|---|---|
| Glass transition temperature (° C.) | | 145 | 155 | 164 | 167 | 172 | 100 | 105 |
| Acid value (mgKOH/g) | | 4 | 5 | 4 | 5 | 2 | 5 | 73 |
| Powder crushing properties | Before | 11 | 17 | 16 | 10 | 25 | 10 | 11 |
| Proportion of particles of | ultrasonic | | | | | | | |
| 10 μm or less [vol %] | wave | | | | | | | |
| | irradiation | | | | | | | |
| | After | 63 | >95 | >95 | 45 | >95 | 35 | 33 |
| | ultrasonic | | | | | | | |
| | wave | | | | | | | |
| | irradiation | | | | | | | |

The abbreviations in the table indicate the following compounds.

“MMA”: methyl methacrylate (Tg of a homopolymer: 105° C.)

“n-BMA”: n-butyl methacrylate (Tg of a homopolymer: 20° C.)

“FA-513M”: dicyclopentanyl methacrylate (Tg of a homopolymer: 175° C.)

“IBXMA”: isobornyl methacrylate (Tg of a homopolymer: 150° C.)

“MAA”: methacrylic acid (Tg of a homopolymer: 228° C.)

### Example 6

100 parts of bisphenol A-type epoxy resin (“JER828” produced by Mitsubishi Chemical Corporation) and 20 parts of the vinyl polymer powder (1) were weighted and then mixed at a rotation speed of 1,200 rpm for 3 minutes under atmospheric pressure using a planetary vacuum mixer (made by THINKY, trade name: “Awatori Rentaro ARV-310LED”) to obtain a mixture. A three-roll mill (“M-80E” made by EXAKT) was used. The obtained mixture was treated by passing through the three-roll mill, at a roll rotation speed of 200 rpm, once at roll intervals of 10 μm and 5 μm, once at roll intervals of 10 μm and 5 μm, and once at roll intervals of 5 μm and 5 μm.

Then, the mixture was again mixed and defoamed at a rotation speed of 1,200 rpm for 2 minutes under a reduced pressure of 3 KPa using the planetary vacuum mixer (made by THINKY, trade name: “Awatori Rentaro ARV-310LED”) to obtain an epoxy resin composition. With respect to the obtained epoxy resin composition, the dispersibility, gelation temperature and gelation performance were evaluated. The result of the evaluation is shown in Table 2.

### Examples 7 to 10, Comparative Examples 4 and 5

Except that the vinyl polymer powders (2) to (7) shown in Table 2 were used in place of the vinyl polymer powder (1), an epoxy resin composition was obtained in the same manner as in Example 6. The dispersibility, gelation temperature and gelation performance of the obtained epoxy resin composition were evaluated. The result of the evaluation is shown in Table 2.

### Comparative Example 3

Except that no vinyl polymer powder was used, an epoxy resin composition was obtained in the same manner as in Example 6. The gelation temperature and gelation performance of the obtained epoxy resin composition were evaluated. The result of the evaluation is shown in Table 2.

TABLE 2

| | | | | | | | Example | Comparative | Comparative | Comparative |
|---|---|---|---|---|---|---|---|---|---|---|
| | | | Example 6 | Example 7 | Example 8 | Example 9 | 10 | Example 3 | Example 4 | Example 5 |
| Mixing | Bis-A type epoxy resin (part) | | 100 | 100 | 100 | 100 | 100 | 100 | 100 | 100 |
| | Vinyl polymer | Type | (1) | (2) | (3) | (4) | (5) | — | (6) | (7) |
| | powder | Addition | 20 | 20 | 20 | 20 | 20 | — | 20 | 20 |
| | | amount (part) | | | | | | | | |
| Evaluation | Dispersibility | Dispersed | <1 | <1 | <1 | <1 | <8 | — | <1 | <1 |
| of epoxy | | particle | | | | | | | | |
| resin | | diameter (mm) | | | | | | | | |
| composition | | Determination | ⊚ | ⊚ | ⊚ | ⊚ | ◯ | — | ⊚ | ⊚ |
| | Evaluation of | Gelation | 98 | 103 | 113 | 88 | 102 | No gelation | 80 | 100 |
| | gelation | temperature | | | | | | | | |
| | properties | (° C.) | | | | | | | | |
| | | G′_{B}/G′_{A} | 280 | 250 | 220 | 240 | 60 | — | 800 | 750 |
| | | Gelation | ◯ | ◯ | ◯ | ◯ | Δ | — | ◯ | ◯ |
| | | performance | | | | | | | | |

### Example 11

100 parts of bisphenol A-type epoxy resin (“JER828” produced by Mitsubishi Chemical Corporation) and 20 parts of the vinyl polymer powder (1) were weighted and then mixed at a rotation speed of 1,200 rpm for 3 minutes under atmospheric pressure using a planetary vacuum mixer (made by THINKY, trade name: “Awatori Rentaro ARV-310LED”) to obtain a mixture. A three-roll mill (“M-80E” made by EXAKT) was used. The obtained mixture was treated by passing through the three-roll mill, at a roll rotation speed of 200 rpm, once at roll intervals of 10 μm and 5 μm, once at roll intervals of 10 μm and 5 μm, and once at roll intervals of 5 μm and 5 μm.

Then, 85 parts of 4-methylhexahydrophthalic anhydride (“Rikacid MH-700” produced by New Japan Chemical Co., Ltd.) as a curing agent for epoxy resin, and 1 part of 2-ethyl-4-methylimidazole (produced by Shikoku Chemical Corporation) as a curing accelerator were added. The resultant was again mixed and defoamed at a rotation speed of 1,200 rpm for 2 minutes under a reduced pressure of 3 KPa using the planetary vacuum mixer (made by THINKY, trade name: “Awatori Rentaro ARV-310LED”) to obtain an epoxy resin composition.

A mold was made by two tempered glass plates having a length of 300 mm, a width of 300 mm and a thickness of 5 mm, wherein a polyethylene terephthalate (PET) film (produced by Toyobo Co., Ltd., trade name: TN200) is attached to a surface of each of the plates, the tempered glass plates are disposed opposite with the surfaces having the PET films thereon face-to-face, and a Teflon (registered trademark) spacer having a thickness of 3 mm is sandwiched between the tempered glass plates. The aforementioned epoxy resin composition flowed into the mold and was fixed by a clamp, followed by being pre-cured at 100° C. for 3 hours, then cured at 120° C. for 4 hours, and then removed from the mold to form a cured product having a thickness of 3 mm.

A test piece was cut from the obtained cured product, and the glass transition temperature, linear expansion coefficient, dielectric constant and dielectric loss tangent thereof were evaluated. The result of the evaluation is shown in Table 3.

### Examples 12 to 15, Comparative Examples 7 and 8

Except that the vinyl polymer powders (2) to (7) shown in Table 3 were used in place of the vinyl polymer powder (1), an epoxy resin cured product was obtained in the same manner as in Example 11. The glass transition temperature, linear expansion coefficient, dielectric constant and dielectric loss tangent of the obtained epoxy resin cured product were evaluated. The result of the evaluation is shown in Table 3.

### Comparative Example 6

Except that no vinyl polymer powder was used, an epoxy resin cured product was obtained in the same manner as in Example 11. The glass transition temperature, linear expansion coefficient, dielectric constant and dielectric loss tangent of the obtained epoxy resin cured product were evaluated. The result of the evaluation is shown in Table 3.

TABLE 3

| | | | | | | | | | Com- | Com- | Com- |
|---|---|---|---|---|---|---|---|---|---|---|---|
| | | | | Example | Example | Example | Example | Example | parative | parative | parative |
| | | | | 11 | 12 | 13 | 14 | 15 | Example 6 | Example 7 | Example 8 |
| Mixing | Bis-A type epoxy resin (part) | | | 100 | 100 | 100 | 100 | 100 | 100 | 100 | 100 |
| | Curing agent (part) | | | 85 | 85 | 85 | 85 | 85 | 85 | 85 | 85 |
| | Curing accelerator (part) | | | 1 | 1 | 1 | 1 | 1 | 1 | 1 | 1 |
| | Vinyl | Type | | (1) | (2) | (3) | (4) | (5) | — | (6) | (7) |
| | polymer | Addition amount (part) | | 20 | 20 | 20 | 20 | 20 | — | 20 | 20 |
| | powder | | | | | | | | | | |
| Evaluation | Glass transition temperature (° C.) | | | 138 | 139 | 139 | 140 | 140 | 140 | 139 | 139 |
| of cured | Linear | α1 | | 72 | 71 | 71 | 72 | 71 | 70 | 78 | 75 |
| product | expansion | (80~100° C.) | | | | | | | | | |
| | coefficient | α2 | | 160 | 155 | 153 | 152 | 162 | 178 | 184 | 181 |
| | (ppm/° C.) | (150~170° C.) | | | | | | | | | |
| | Electrical | Relative | Result | 2.88 | 2.86 | 2.86 | 2.86 | 2.85 | 3.05 | 2.98 | 2.97 |
| | properties | dielectric | Determination | ◯ | ◯ | ◯ | ◯ | ◯ | X | Δ | Δ |
| | | constant | | | | | | | | | |
| | | Dielectric | Result | 0.0088 | 0.0087 | 0.0087 | 0.0088 | 0.0086 | 0.0092 | 0.0090 | 0.0090 |
| | | loss tangent | Determination | ◯ | ◯ | ◯ | ◯ | ◯ | ◯ | ◯ | ◯ |

### Example 16

Except that 100 parts of hydrogenated bisphenol A-type epoxy resin (“YX-8000” produced by Mitsubishi Chemical Corporation) in place of the bisphenol A-type epoxy resin, 77 parts of 4-methylhexahydrophthalic anhydride (“Rikacid MH-700” produced by New Japan Chemical Co., Ltd.) as a curing agent for epoxy resin, and 1 part of 2-ethyl-4-methylimidazole (produced by Shikoku Chemical Corporation) as a curing accelerator were used, an epoxy resin cured product was obtained in the same manner as in Example 11. The glass transition temperature, linear expansion coefficient, dielectric constant and dielectric loss tangent of the obtained epoxy resin cured product were evaluated. The result of the evaluation is shown in Table 4.

### Examples 17 to 20, Comparative Examples 10 and 11

Except that the vinyl polymer powders (2) to (7) shown in Table 4 were used in place of the vinyl polymer powder (1), an epoxy resin cured product was obtained in the same manner as in Example 16. The glass transition temperature, linear expansion coefficient, dielectric constant and dielectric loss tangent of the obtained epoxy resin cured product were evaluated. The result of the evaluation is shown in Table 4.

### Comparative Example 9

Except that no vinyl polymer powder was used, an epoxy resin cured product was obtained in the same manner as in Example 16. The glass transition temperature, linear expansion coefficient, dielectric constant and dielectric loss tangent of the obtained epoxy resin cured product were evaluated. The result of the evaluation is shown in Table 4.

TABLE 4

| | | | | | | | | | | Com- | Com- |
|---|---|---|---|---|---|---|---|---|---|---|---|
| | | | | | | | | | Com- | parative | parative |
| | | | | Example | Example | Example | Example | Example | parative | Example | Example |
| | | | | 16 | 17 | 18 | 19 | 20 | Example 9 | 10 | 11 |
| Mixing | Hydrogenated bis-A type epoxy resin | | | 100 | 100 | 100 | 100 | 100 | 100 | 100 | 100 |
| | (part) | | | | | | | | | | |
| | Curing agent (part) | | | 77 | 77 | 77 | 77 | 77 | 77 | 77 | 77 |
| | Curing accelerator (part) | | | 1 | 1 | 1 | 1 | 1 | 1 | 1 | 1 |
| | Vinyl | Type | | (1) | (2) | (3) | (4) | (5) | — | (6) | (7) |
| | polymer | Addition amount (part) | | 20 | 20 | 20 | 20 | 20 | — | 20 | 20 |
| | powder | | | | | | | | | | |
| Evaluation | Glass transition temperature (° C.) | | | 126 | 127 | 127 | 127 | 127 | 128 | 126 | 126 |
| of cured | Linear | α1 | | 65 | 63 | 60 | 65 | 62 | 65 | 68 | 68 |
| product | expansion | (80-100° C.) | | | | | | | | | |
| | coefficient | α2 | | 165 | 164 | 159 | 156 | 165 | 176 | 186 | 183 |
| | (ppm/° C.) | (140-160° C.) | | | | | | | | | |
| | Electrical | Relative | Result | 2.86 | 2.86 | 2.81 | 2.82 | 2.80 | 3.02 | 3.03 | 2.98 |
| | properties | dielectric | Determination | ◯ | ◯ | ◯ | ◯ | ◯ | X | X | Δ |
| | | constant | | | | | | | | | |
| | | Dielectric | Result | 0.0086 | 0.0086 | 0.0085 | 0.0086 | 0.0085 | 0.0087 | 0.0088 | 0.0087 |
| | | loss tangent | Determination | ◯ | ◯ | ◯ | ◯ | ◯ | ◯ | ◯ | ◯ |

### Evaluation

From Table 2, it is known that the vinyl polymer powders (1) to (5) of the invention had excellent dispersibility in the epoxy resin, and the epoxy resin compositions including the vinyl polymer powders (1) to (5) had high gelation performance (Examples 6 to 10). On the other hand, in the epoxy resin composition in Comparative Example 3, which does not include the vinyl polymer powder of the invention, no gelation performance was observed (Comparative Example 3).

From Table 3 and Table 4, it is known that the cured products obtained by curing the epoxy resin compositions including the vinyl polymer powders (1) to (5) of the invention were recognized to have an effect of suppressing an increase in linear expansion coefficient (Examples 11 to 20). An organic material is increased in linear expansion coefficient in a region of temperatures equal to or greater than the glass transition temperature. However, the cured products including the vinyl polymer powders (1) to (5) of the invention suppress the increase in linear expansion coefficient at equal to or greater than the glass transition temperature. According to this result, it may be expected to improve the crack resistance of the epoxy resin composition, and to suppress the crack destruction caused by temperature cycles.

Furthermore, the cured products obtained by curing the epoxy resin compositions including the vinyl polymer powders (1) to (5) of the invention have low dielectric constant and dielectric loss tangent as well as excellent electrical properties.

On the other hand, the cured products having a glass transition temperature of lower than 120° C. and obtained by curing the epoxy resin compositions including the vinyl polymer powders (6) and (7) which are outside the scope of the invention were increased in linear expansion coefficient as compared to the cured products including no vinyl polymer powder. In addition, the electrical properties were at a low level (Comparative Examples 7, 8, 10 and 11).

### INDUSTRIAL USABILITY

The vinyl polymer powder of the invention may be used as a pre-gelatinizing agent for an electronic material that has an excellent dispersibility in a curable resin, especially epoxy resin, and exhibits excellent electrical properties by rapidly turning a curable resin composition into a gel state by heating at a predetermined temperature in a short time.

Furthermore, the vinyl polymer powder is applicable to a variety of uses as follows: liquid sealing materials, such as underfilling materials for primary mounting, underfilling materials for secondary mounting, glob top materials in wire bonding, etc.; sealing sheets for collective sealing of various chips on a substrate; pre-dispensing type underfilling materials; sealing sheets for collective sealing at a wafer level; adhesion layers for three-layered copper clad laminate; adhesion layers, such as die bond films, die attach films, interlayer insulating films, cover-lay films, etc.; adhesive pastes, such as die bond pastes, interlayer insulating pastes, conductive pastes, anisotropic conductive pastes, etc.; sealing materials of light-emitting diode; optical adhesives; sealing materials of various flat panel displays such as liquid crystal and organic electroluminescence (EL) displays, etc.

What is claimed is:

1. A vinyl polymer powder, comprising a vinyl polymer having a glass transition temperature of 120° C. or higher and a mass average molecular weight of 100,000 or more.

2. The vinyl polymer powder of claim 1, comprising 50 mass % or more of a monomer unit having a homopolymer glass transition temperature of 120° C. or higher.

3. The vinyl polymer powder of claim 1, comprising 50 to 98 mass % of a monomer unit having a homopolymer glass transition temperature of 120° C. or higher, and 50 to 2 mass % of other monomer unit.

4. The vinyl polymer powder of claim 2, comprising 70 mass % or more of a monomer unit having a homopolymer glass transition temperature of 120° C. or higher.

5. The vinyl polymer powder of claim 2, wherein a molar volume of the monomer unit having a homopolymer glass transition temperature of 120° C. or higher is 150 cm³/mol or more.

6. The vinyl polymer powder of claim 2, wherein the monomer unit having a homopolymer glass transition temperature of 120° C. or higher is at least one selected from the group consisting of an alicyclic (meth)acrylate unit, a methacrylic acid unit, a vinyl cyanide monomer unit and a styrene derivative unit.

7. The vinyl polymer powder of claim 6, wherein the monomer unit having a homopolymer glass transition temperature of 120° C. or higher is the alicyclic (meth)acrylate unit.

8. The vinyl polymer powder of claim 7, wherein the alicyclic (meth)acrylate unit is at least one selected from the group consisting of a dicyclopentanyl methacrylate unit and an isobornyl methacrylate unit.

9. The vinyl polymer powder of claim 3, wherein the other monomer unit is an alkyl (meth)acrylate unit.

10. The vinyl polymer powder of claim 1, wherein a volume average primary particle diameter is 0.2 μm or more and 8 μm or less.

11. The vinyl polymer powder of claim 1, wherein a content of alkali metal ions is 10 ppm or less.

12. The vinyl polymer powder of claim 1, wherein an acid value is 50 mgKOH/g or less.

13. The vinyl polymer powder of claim 1, wherein particles having a particle diameter of 10 μm or less account for less than 30 volume % of the vinyl polymer powder, and the particles having a particle diameter of 10 μm or less account for 30 volume % or more of the vinyl polymer powder after irradiation of an ultrasonic wave having a frequency of 42 kHz and an output of 40 W for 5 minutes.

14. A pre-gelatinizing agent for a curable resin, comprising the vinyl polymer powder of claim 1.

15. A curable resin composition, comprising the vinyl polymer powder of claim 1 and a curable resin.

16. The curable resin composition of claim 15, wherein the curable resin is an epoxy resin.

17. A cured product obtained by curing the curable resin composition of claim 15.

18. A semiconductor sealing material using the curable resin composition of claim 15.
